(19) United States
(12) Patent Application Publication
(10) Pub. No.: US 2022/0262970 A1
(43) Pub. Date: Aug. 18, 2022

(54) LIGHT RECEIVING ELEMENT AND ELECTRONIC DEVICE

(71) Applicant: SONY SEMICONDUCTOR SOLUTIONS CORPORATION, Kanagawa (JP)

(72) Inventor: Hiroaki MURAKAMI, Kanagawa (JP)

(73) Assignee: SONY SEMICONDUCTOR SOLUTIONS CORPORATION, Kanagawa (JP)

(21) Appl. No.: 17/626,249

(22) PCT Filed: Jul. 29, 2020
(86) PCT No.: PCT/JP2020/029147

§ 371 Date: Jan. 11, 2022

(30) Foreign Application Priority Data
Jul. 31, 2019 (JP) 2019-141690

(51) Int. Cl. H01L 31/0352; H01L 31/0224; H01L 27/146; H01L 31/0216; G01S 7/481; G01S 17/10; G01S 7/4865

(52) U.S. Cl. CPC H01L 31/035272; H01L 31/022408; H01L 31/022416; H01L 27/1462; H01L 27/14603; H01L 31/107; G01S 7/4814; G01S 17/10; G01S 7/4816; G01S 7/4865; H01L 31/02161

(57) ABSTRACT

An embodiment of the present technology includes an avalanche photodiode including a substrate including a first side with a first surface and a second side with a second surface that is opposite the first surface. The second surface is a light-incident surface of the substrate. The avalanche photodiode includes an anode region disposed in the substrate at the first side of the substrate, an anode electrode coupled to the anode region, a cathode region disposed in the substrate at the first side of the substrate, a cathode electrode coupled to the cathode region, and an insulating layer disposed in the substrate at the first side of the substrate. The anode electrode or the cathode electrode passes through the insulating layer.

### TECHNICAL FIELD

This disclosure relates to light receiving elements and electronic devices.

### BACKGROUND ART

There has been known a distance-measurement technique referred to as a direct time-of-flight (ToF) scheme, as one of distance-measurement schemes to measure the distance to a measurement object using light. In such a direct ToF scheme, a light receiving element receives reflected light that is reflection of light emitted from a light source reflected on a measurement object, and the distance to the target is measured based on time after light is emitted until the light is received as reflected light (e.g., see PTL 1).

### CITATION LIST

### Patent Literature

PTL 1: JP 2004-319576 A

### SUMMARY

### Technical Problem

The present disclosure presents a light receiving element and an electronic device that can achieve relaxation of an electric field between a cathode contact region and an anode contact region while preventing the area of the light receiving element from expanding.

### Solution to Problem

An embodiment of the present technology includes a light receiving element includes a single photon avalanche diode (SPAD) element formed in a semiconductor layer and provided for each of pixels disposed into an array form. The light receiving element includes a cathode electrode and an anode electrode formed at least partially in a wiring layer adjacent to the semiconductor layer and configured to apply a reverse bias voltage to the SPAD element, an N-type cathode contact region formed in the semiconductor layer and directly connected to the cathode electrode, a P-type anode contact region formed in the semiconductor layer and directly connected to the anode electrode, and an insulating buried layer located between either one of the cathode contact region and the anode contact region, and a surface on an opposite side to a light incident side of the semiconductor layer. The light receiving element includes a surface pinning layer formed in the surface on the opposite side to the light incident side of the semiconductor layer and connected to a ground potential. The light receiving element includes an N-type diffusion layer in contact with the cathode contact region in the semiconductor layer. A gap between the N-type diffusion layer and the surface on the opposite side to the light incident side of the semiconductor layer is covered with the buried layer.

An embodiment of the present technology includes an electronic device including a light receiving element. The light receiving element includes a single photon avalanche diode (SPAD) element formed in a semiconductor layer and provided for each of pixels disposed into an array form, a cathode electrode and an anode electrode formed at least partially in a wiring layer adjacent to the semiconductor layer and configured to apply a reverse bias voltage to the SPAD element, an N-type cathode contact region formed in the semiconductor layer and directly connected to the cathode electrode, a P-type anode contact region formed in the semiconductor layer and directly connected to the anode electrode, and an insulating buried layer located between either one of the cathode contact region and the anode contact region, and a surface on an opposite side to a light incident side of the semiconductor layer. The light receiving element further comprises a surface pinning layer formed in the surface on the opposite side to the light incident side of the semiconductor layer and connected to a ground potential. The light receiving element further comprises an N-type diffusion layer in contact with the cathode contact region in the semiconductor layer, and a gap between the N-type diffusion layer and the surface on the opposite side to the light incident side of the semiconductor layer is covered with the buried layer.

An embodiment of the present technology includes an avalanche photodiode including a substrate including a first side with a first surface and a second side with a second surface that is opposite the first surface. The second surface is a light-incident surface of the substrate. The avalanche photodiode includes an anode region disposed in the substrate at the first side of the substrate, an anode electrode coupled to the anode region, a cathode region disposed in the substrate at the first side of the substrate, a cathode electrode coupled to the cathode region, and an insulating layer disposed in the substrate at the first side of the substrate. The anode electrode or the cathode electrode passes through the insulating layer. In a plan view, the cathode electrode is disposed closer to a center of the avalanche photodiode than the anode electrode. In the plan view, the cathode electrode surrounds the center of the avalanche photodiode. In the plan view, the cathode electrode is spaced apart from and surrounds the center of the avalanche photodiode. In the plan view, the cathode electrode is contiguous. All sides of the cathode electrode are spaced apart from the center of the avalanche photodiode at a same distance. In the plan view, the cathode electrode includes a plurality of cathode portions spaced apart from one another by the insulating layer. Each cathode portion is spaced apart from the center of the avalanche photodiode at a same distance. In the plan view, the insulating layer extends between two sides of the cathode electrode. A surface of the insulating layer is coplanar with the first surface of the substrate. The insulating layer extends deeper into the substrate than the anode contact region. The avalanche photodiode includes a doped region extending between two sides of the insulating layer. The avalanche photodiode includes a contact electrode coupled to the doped region and to a node that receives a potential. The potential may be a ground potential.

According to an embodiment of the present technology, a light detecting device includes a first substrate including a first side with a first surface and a second side with a second surface that is opposite the first surface. The second surface is a light-incident surface of the first substrate. The light detecting device includes an avalanche photodiode including an anode region disposed in the first substrate at the first side of the first substrate, an anode electrode coupled to the anode region, a cathode region disposed in the first substrate at the first side of the first substrate, an insulating layer disposed in the first substrate at the first side of the first substrate, and a cathode electrode coupled to the cathode region. The cathode electrode or the anode electrode passes through the insulating layer. The light detecting device includes a first wiring layer on the first surface of the first substrate and including an anode wiring coupled to the anode electrode, a cathode wiring coupled to the cathode electrode, and a plurality of first bonding pads. The light detecting device includes a second substrate including a second wiring layer and circuitry to process signals output from the avalanche photodiode. The second wiring layer includes a plurality of second bonding pads bonded to the plurality of first bonding pads. The plurality of first bonding pads and the plurality of second bonding pads each include a bonding pad electrically connected to the anode wiring and a bonding pad electrically connected to the cathode wiring. In a plan view, the cathode electrode is disposed closer to a center of the avalanche photodiode than the anode electrode. In the plan view, the cathode electrode surrounds the center of the avalanche photodiode. In the plan view, the cathode electrode is spaced apart from and surrounds the center of the avalanche photodiode.

An embodiment of the present technology is directed to an electronic apparatus including a light source that emits modulated light toward and object, and an avalanche photodiode that senses the modulated light reflected from the object. The avalanche photodiode includes a substrate including a first side with a first surface and a second side with a second surface that is opposite the first surface. The second surface is a light-incident surface of the substrate. The avalanche photodiode includes an anode region disposed in the substrate at the first side of the substrate, an anode electrode coupled to the anode region, a cathode region disposed in the substrate at the first side of the substrate, an insulating layer disposed in the substrate at the first side of the substrate, and a cathode electrode coupled to the cathode region. The cathode electrode or the anode electrode passes through the insulating layer.

### Advantageous Effects of Invention

The present disclosure can achieve the relaxation of the electric field between the anode contact region and the cathode contact region while preventing the area of the light receiving element from expanding. Note that the effect described here is not necessarily limited, and may be any effects described in the present disclosure.

### BRIEF DESCRIPTION OF DRAWINGS

FIG. 1 is a view schematically illustrating distance measurement by a direct ToF scheme applicable to an embodiment of the present disclosure.

FIG. 2 is a view illustrating one example of a histogram based on time when a light receiving chip applicable to the embodiment of the present disclosure receives light.

FIG. 3 is a block diagram illustrating a configuration example of the light receiving chip according to the embodiment of the present disclosure.

FIG. 4 is a sectional view illustrating a configuration example of a pixel array part according to the embodiment of the present disclosure.

FIG. 5 is a view illustrating one example of a planer configuration at a depth D1 illustrated in FIG. 4.

FIG. 6 is a view illustrating another example of the planer configuration at the depth D1 illustrated in FIG. 4.

FIG. 7 is a sectional view schematically illustrating one manufacturing process of the pixel array part according to the embodiment of the present disclosure.

FIG. 8 is a sectional view schematically illustrating one manufacturing process of the pixel array part according to the embodiment of the present disclosure.

FIG. 9 is a sectional view schematically illustrating one manufacturing process of the pixel array part according to the embodiment of the present disclosure.

FIG. 10 is a sectional view schematically illustrating one manufacturing process of the pixel array part according to the embodiment of the present disclosure.

FIG. 11 is a sectional view schematically illustrating one manufacturing process of the pixel array part according to the embodiment of the present disclosure.

FIG. 12 is a sectional view schematically illustrating one manufacturing process of the pixel array part according to the embodiment of the present disclosure.

FIG. 13 is a sectional view illustrating a configuration example of a pixel array part according to a first variation of the embodiment of the present disclosure.

FIG. 14 is a sectional view illustrating a configuration example of a pixel array part according to a second variation of the embodiment of the present disclosure.

FIG. 15 is a sectional view illustrating a configuration example of a pixel array part according to a third variation of the embodiment of the present disclosure.

FIG. 16 is a block diagram illustrating one example of a schematic configuration of an electronic device.

FIG. 17 is a block diagram illustrating one example of a schematic configuration of a vehicle control system.

FIG. 18 is an illustrative view illustrating one example of an installation position of an outer-vehicle-information detecting part and an imaging part.

### DESCRIPTION OF EMBODIMENTS

Respective embodiments of the present disclosure will now be described in detail based on the drawings. Note that, in each of the following embodiments, the same part is indicated by the same number and thus redundant description is omitted.

There has been known a distance-measurement technique referred to as a direct time-of-flight (ToF) scheme, as one of distance-measurement schemes to measure the distance to a measurement object using light. In such a direct ToF scheme, a light receiving element receives reflected light that is reflection of light emitted from a light source reflected on a measurement object, and the distance to the target is measured based on time after light is emitted until the light is received as reflected light.

Such a distance-measurement technique uses a light receiving element that includes a single photon avalanche diode (SPAD) element therein. Such an SPAD element applies, between an anode and a cathode, a large reverse bias voltage (e.g., in the order of −20 V) at which avalanche multiplication occurs, and thus internally generates avalanche multiplication caused by electrons occurring in response to the incidence of one photon. This enables the incidence of one photon included in the reflected light to be detected with high sensitivity.

However, on the back side of a semiconductor layer where the SPAD element is formed, the large reverse bias voltage is applied between a cathode contact region and an anode contact region adjacent to each other. This yields an electric field concentrated between the cathode contact region and the anode contact region and may pose a problem, such as poor dark-current properties.

In contrast, as described in the conventional art, forming a shallow trench isolation (STI) between the cathode contact region and the anode contact region results in the problem that the area of the light receiving element increases by the amount of such an STI.

There are expectations for implementing a light receiving element and an electronic device that can achieve the relaxation of the electric field between the cathode contact region and the anode contact region while overcoming the above-mentioned problem and preventing the area of the light receiving element from expanding.

Method of Measuring Distance

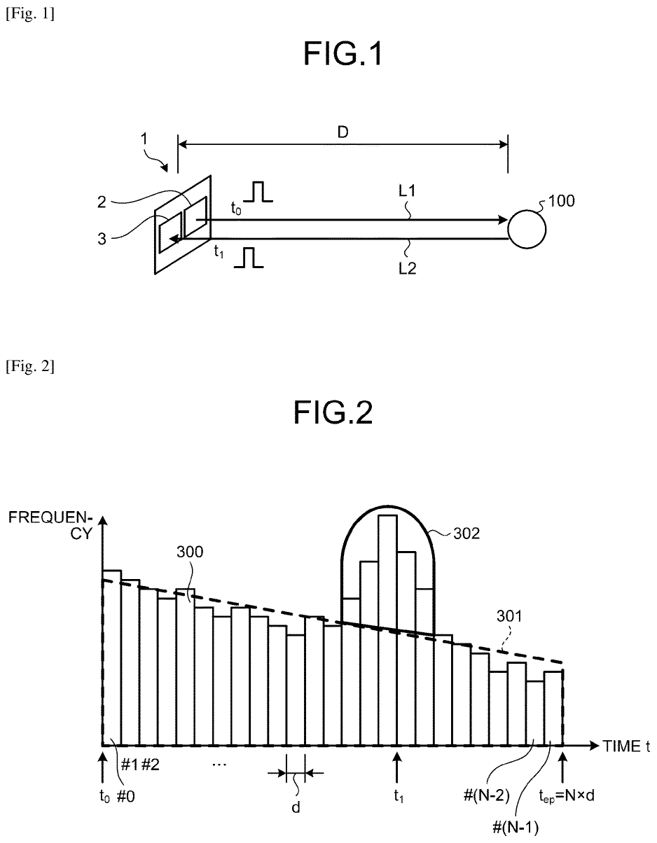

The present disclosure relates to a technology for performing distance measurement using light. For easy understanding of the embodiment of the present disclosure, a method of measuring distance applicable to the embodiment will described with reference to FIGS. 1 and 2.

FIG. 1 is a view schematically illustrating distance measurement by the direct ToF scheme applicable to the embodiment of the present disclosure. To the embodiment, the direct ToF scheme is applied as a distance-measurement scheme.

Such a direct ToF scheme is a scheme where a light receiving chip 3 receives a reflected light L2 that is reflection of emitted light L1 from a light source 2 reflected on a measurement object 100, and distance measurement is performed based on the difference time between the timing of the light emission and the light reception timing.

A distance-measurement device 1 includes the light source 2 and the light receiving chip 3. For example, the light source 2 is a laser diode and driven to emit laser light in a pulsed manner.

The emitted light L1 from the light source 2 is reflected on the measurement object 100 and received by the light receiving chip 3 as the reflected light L2. The light receiving chip 3 converts the light into an electrical signal through photoelectric conversion and outputs a signal corresponding to the received light.

Here, time t₀ is referred to as time (light emission timing) when the light source 2 emits light, and time t₁ is referred to as time (light reception timing) when the light receiving chip 3 receives the reflected light L2 that is reflection of the emitted light L1 from the light source 2 reflected on the measurement object 100.

Assuming the speed of light (2.9979×10⁸ [m/sec]) as a constant c, the distance D between the distance-measurement device 1 and the measurement object 100 can be calculated with the following expression (1).

D=(c/2)×(t₁−t₀) (1)

More specifically, the distance-measurement device 1 classifies, based on ranks (bins), time tₘ (hereinafter, also referred to as “light reception time tₘ”) from the time to at the light emission timing until the light reception timing when the light receiving chip 3 receives the light, and generates a histogram.

FIG. 2 is a view illustrating one example of a histogram based on the time when the light receiving chip 3 applicable to the embodiment of the present disclosure receives the light. In FIG. 2, a horizontal axis represents bins, and a vertical axis represents a frequency for each bin. The bins are such that the light reception time tₘ is classified for every predetermined unit time d.

Specifically, a bin #0 is 0≤tₘ≤d, a bin #1 is d≤tₘ<2×d, a bin #2 is 2×d≤tₘ<3×d, . . . , and a bin #(N−2) is (N−2)×d≤tₘ<(N−1)×d. Assuming exposure time of the light receiving chip 3 as time tₑₚ, tₑₚ=N×d.

The distance-measurement device 1 counts the number of times of acquiring the light reception time tₘ based on the bins to determine a frequency 300 for each bin and generate a histogram. Here, the light receiving chip 3 also receives light other than the reflected light L2 that is reflection of the emitted light L1 from the light source 2.

For example, an example of the light other than the reflected light L2 to be targeted includes environmental light around the distance-measurement device 1. Such environmental light is light incident on the light receiving chip 3 at random, and an environment light component 301 of the environmental light in the histogram is a noise on the reflected light L2 to be targeted.

In contrast, the reflected light L2 to be targeted is light received correspondingly to a particular distance and appears as an active light component 302 in the histogram. The bin corresponding to the frequency of a peak in this active light component 302 is the bin corresponding to the distance D of the measurement object 100.

The distance-measurement device 1 acquires representative time of this bin (e.g., center time of the bin) as t₁ described above and thus can calculate the distance D to the measurement object 100 according to the expression (1) described above. In this way, using a plurality of light reception results enables the distance measurement appropriate with respect to random noise to be executed.

Configuration of Light Receiving Chip

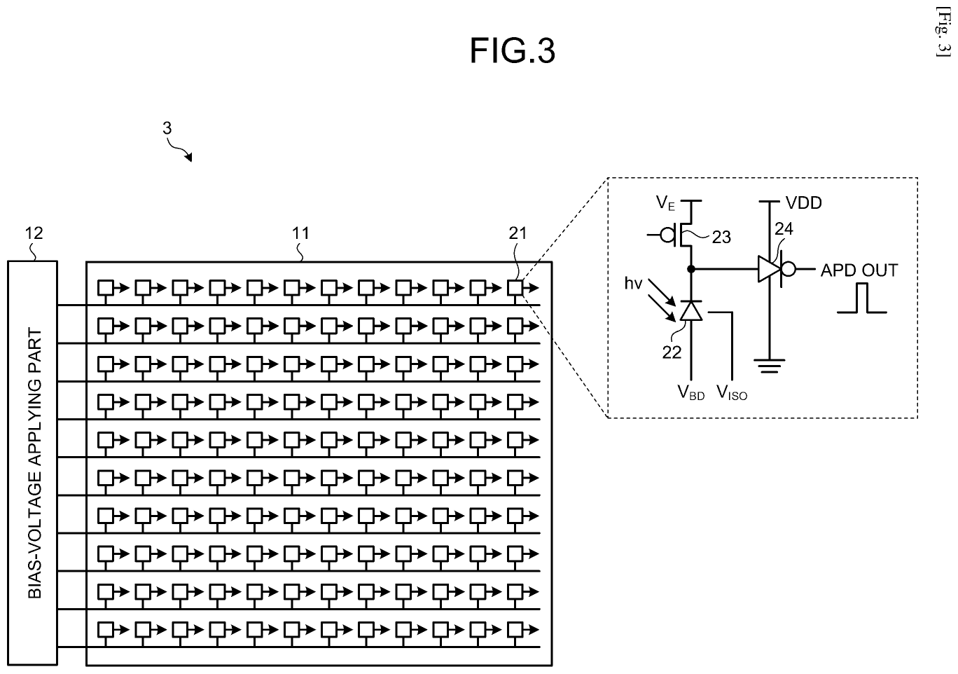

Next, the configuration of the light receiving chip 3 according to the embodiment will be described with reference to FIG. 3. FIG. 3 is a block diagram illustrating a configuration example of the light receiving chip 3 according to the embodiment of the present disclosure. As illustrated in FIG. 1, the light receiving chip 3 according to the embodiment includes a pixel array part 11 and a bias-voltage applying part 12. The pixel array part 11 is one example of the light receiving element or light detecting device.

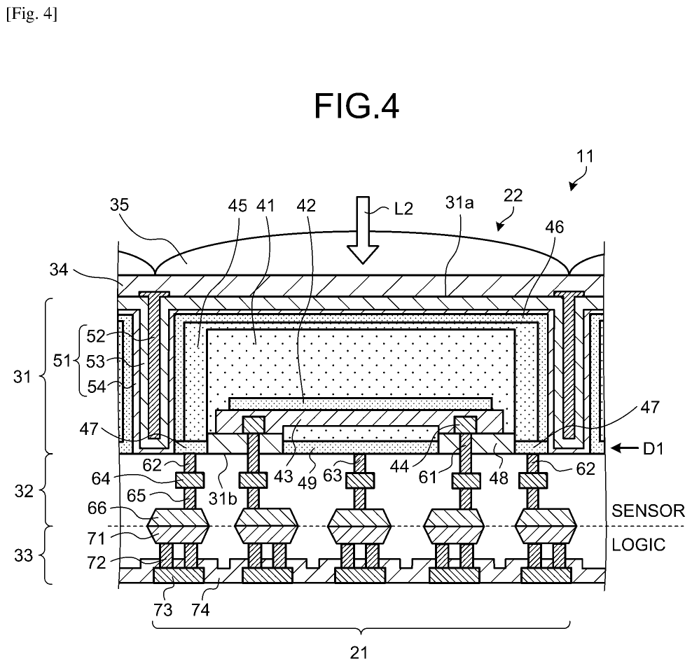

The pixel array part 11, a plurality of pixels 21 of which are disposed into an array form, has a light receiving surface to receive the reflected light L2 (see FIG. 4) condensed by an optical system, such as an on-chip lens 35 (see FIG. 4). The configuration of such a pixel array part 11 will be described below.

For example, as illustrated on the right side of FIG. 3, the pixel 21 includes an SPAD element (or avalanche photodiode) 22 and a P-type metal-oxide-semiconductor field-effect transistor (MOSFET) 23, and a CMOS inverter 24.

By applying a large negative voltage V_{BD} (e.g., in the order of −20 V) between an anode and a cathode, the SPAD element 22 can form an avalanche-multiplication region and avalanche-multiply electrons occurring at the incidence of one photon.

When a voltage caused by the electrons avalanche-multiplied by the SPAD element 22 reaches the negative voltage V_{BD}, the P-type MOSFET 23 releases the electrons multiplied by the SPAD element 22 and performs quenching to return to its initial voltage.

The CMOS inverter 24 shapes the voltage generated by the electrons multiplied by the SPAD element 22, thereby outputting a light reception signal (APD OUT) where a pulse waveform occurs assuming the arrival time of one photon as an initial point.

The bias-voltage applying part 12 applies a reverse bias voltage to each of the pixels 21 disposed in the pixel array part 11.

From the light receiving chip 3 configured in this way, each pixel 21 outputs the light reception signal and supplies it to a subsequent operation processing part, which is not shown. For example, such an operation-processing part performs operation processing to determine the distance D to the measurement object 100 based on the timing when a pulse indicating the arrival time of one photon occurs in each light reception signal, and determines the distance D for each pixel 21.

Based on the determined distances D, a range image where each distance D to the measurement object 100 detected by each pixel 21 is planarly arranged is generated.

Configuration of Pixel Array Part

Next, the configuration of the pixel array part 11 according to the embodiment will be described with reference to FIGS. 4 to 6. FIG. 4 is a sectional view illustrating a configuration example of the pixel array part 11 according to the embodiment of the present disclosure.

As illustrated in FIG. 4, the pixel array part 11 according to the embodiment includes a semiconductor layer (or substrate) 31, a sensor-side wiring layer 32, a logic-side wiring layer 33, a planarized layer 34, and an on-chip lens 35. Although not explicitly shown, a color filter (e.g., red, green, or blue filter) may be placed between the planarized layer 34 and the on-chip lens 35 to enable color imaging. The sensor-side wiring layer 32 is one example of a wiring layer.

In order from the side where the reflected light L2 is incident, the on-chip lens 35, the planarized layer 34, the semiconductor layer 31, the sensor-side wiring layer 32, and the logic-side wiring layer 33 are stacked, so that the pixel array part 11 is configured.

Furthermore, a logic-side substrate, which is not shown, is further stacked on the logic-side wiring layer 33. Such a logic-side substrate has, for example, the bias-voltage applying part 12, the P-type MOSFET 23, and the CMOS inverter 24, which are illustrated in FIG. 3. The logic-side substrate may include circuitry (e.g., signal processing circuitry and/or logic circuitry) for processing signals from the pixel array part 11.

For example, the sensor-side wiring layer 32 is formed on the semiconductor layer 31 while the logic-side wiring layer 33 is formed on a logic-circuit board. After that, the pixel array part 11 can be manufactured by a manufacturing method to bond the sensor-side wiring layer 32 and the logic-side wiring layer 33 at a bonding surface (surface illustrated by a broken line in FIG. 4).

For example, a technique to bond the sensor-side wiring layer 32 and the logic-side wiring layer 33 can include what is called “Cu—Cu bonding”, where a Cu pad is exposed on each of both bonding interfaces and electrical conduction is also secured by directly bonding both such Cu pads.

For example, in the semiconductor layer 31, which is a layer obtained by thinly grinding a semiconductor substrate, such as single-crystal silicon, its P-type or N-type impurity concentration is controlled, and the SPAD element 22 is formed for each pixel 21.

The upside surface of the semiconductor layer 31 in FIG. 4 is considered as an incident surface 31a, on which the reflected light L2 is incident, and the sensor-side wiring layer 32 is stacked on an opposite surface 31b, which is the opposite side to this incident surface 31a.

The sensor-side wiring layer 32 and the logic-side wiring layer 33 have wiring for supplying a voltage applied to the SPAD element 22, wiring for taking the electrons generated by the SPAD element 22 out of the semiconductor layer 31, and other wiring.

The SPAD element 22 is configured with a P well 41, a P-type diffusion layer 42, an N-type diffusion layer 43, a cathode contact region (or cathode region) 44, a hole-accumulating layer 45, a pinning layer (or doped region) 46, and an anode contact region (or anode region) 47 formed in the semiconductor layer 31. Although FIGS. 4-6 illustrate various shapes for the cathode and regions 44 and 47, it should be appreciated that other configurations are possible. For example, the anode region 47 and/or the cathode region 44 may be a region that appears only once in a cross-sectional view. In the SPAD element 22, an avalanche-multiplication region is formed of a depletion layer formed in a bonding region between the P-type diffusion layer 42 and the N-type diffusion layer 43.

Such an avalanche-multiplication region is a high-electric-field region formed in the boundary surface between the P-type diffusion layer 42 and the N-type diffusion layer 43 by applying a large negative voltage to the N-type diffusion layer 43, and multiplies the electrons occurring at the incidence of one photon on the SPAD element 22.

The P well 41 is formed by controlling the impurity concentration of the semiconductor layer 31 to be P-type, and forms an electric field that transfers the electrons occurring through the photoelectric conversion in the SPAD element 22 to the avalanche-multiplication region. Note that, instead of the P well 41, the impurity concentration of the semiconductor layer 31 may be controlled to be N-type such that an N well is formed.

The P-type diffusion layer 42 is a concentrated P-type diffusion layer (P+) that is in the vicinity of the opposite surface 31b of the semiconductor layer 31 and is formed on the incident surface 31a side (upper side of FIG. 4) relative to the N-type diffusion layer 43, and is formed over the almost whole of the SPAD element 22.

The N-type diffusion layer 43 is an N-type diffusion layer (N) that is in the vicinity of the opposite surface 31b of the semiconductor layer 31 and is formed on the opposite surface 31b side (lower side of FIG. 4) relative to the P-type diffusion layer 42, and is formed over the almost whole of the SPAD element 22.

The cathode contact region 44 is a concentrated N-type diffusion layer (N+) formed on the opposite surface 31b side (lower side of FIG. 4) inside the N-type diffusion layer 43. Such a cathode contact region 44 is directly connected to a cathode electrode 61 that supplies a voltage to form the avalanche-multiplication region in the N-type diffusion layer 43.

The hole-accumulating layer 45 is a P-type diffusion layer (P) formed to surround a side surface of the P well 41 and a surface on the light incident side thereof, and accumulates holes. Furthermore, the hole-accumulating layer 45 is electrically connected to the anode of the SPAD element 22 and has an ability to adjust bias.

This enhances the hole concentration of the hole-accumulating layer 45, so that pinning including the pinning layer 46 can be strengthened. The embodiment thus enables the occurrence of dark current to be reduced.

The pinning layer 46 is a concentrated P-type diffusion layer (P+) formed on a surface (side surface in contact with the incident surface 31a of the semiconductor layer 31 and an inter-pixel separating part 51) outside the hole-accumulating layer 45, and, for example, reduces the occurrence of dark current, similarly to the hole-accumulating layer 45.

The anode contact region 47 is a concentrated P-type diffusion layer (P+) formed to be in contact with the pinning layer 46 in the vicinity of the opposite surface 31b of the semiconductor layer 31. Such an anode contact region 47 is directly connected to an anode electrode 62 that supplies a voltage to form the avalanche-multiplication region in the P-type diffusion layer 42 via the pinning layer 46, the hole-accumulating layer 45, and the P well 41.

Here, in the embodiment, an insulating buried layer (or insulating layer) 48 is provided between either one of the cathode contact region 44 and the anode contact region 47, and the opposite surface 31b of the semiconductor layer 31. In the example of FIG. 4, the buried layer 48 is provided between the cathode contact region 44 and the opposite surface 31b of the semiconductor layer 31. In a plan view, the cathode electrode 61 is disposed closer to a center of the avalanche photodiode 22 than the anode electrode 62. The center of the avalanche photodiode 22 may be coincident with an optical axis of the on-chip lens 35. As shown in FIG. 4, a surface of the insulating layer 48 is coplanar with the first surface of the substrate 31. The insulating layer 48 may extend deeper into the substrate 31 than the anode contact region 47. The cathode electrode 61 or the anode electrode 62 may pass through the insulating layer 48. In the example of FIG. 4, the cathode electrode 61 passes through the insulating layer 48. However, it should be appreciated that the roles of certain elements of the avalanche photodiode 22 may be reversed, which may cause changes in design. For example, as should be understood by one skilled in the art, certain n-type regions may be swapped for p-type regions and certain p-type regions may be swapped for n-type regions. In this case, the anode electrode 62 may pass through an insulating layer 48.

For example, the buried layer 48 is configured with an insulator, such as silicon oxide (SiO₂). The cathode electrode 61 formed in the sensor-side wiring layer 32 penetrates through such a buried layer 48 and is directly connected to the cathode contact region 44.

By providing the buried layer 48 in this way, a gap between the anode contact region 47 and the cathode contact region 44 to which the large reverse bias voltage is applied can be insulated and separated while being spaced not only in a horizontal direction but also in a vertical direction.

That is, while the distance between the cathode contact region 44 and the anode contact region 47 are kept in the horizontal direction, the cathode contact region 44 and the anode contact region 47 can be spaced by a distance where relaxation of an electric-field therebetween can be achieved in total.

The embodiment thus can achieve the relaxation of the electric field between the cathode contact region 44 and the anode contact region 47 while preventing the area of the pixel array part 11 from expanding.

The description of other parts in the pixel array part 11 is continued. The surface pinning layer 49 is a concentrated P-type diffusion layer (P+) formed in a place other than the anode contact region 47, the buried layer 48, and the inter-pixel separating part 51, in the opposite surface 31b of the semiconductor layer 31. The surface pinning layer 49 is connected to a ground potential via the contact electrode 63. In other words, a doped region 49 extends between two sides of the insulating layer 49, and the contact electrode 63 is coupled to the doped region 49 and to a node that receives a potential, for example, a ground potential.

Providing such a surface pinning layer 49 enables the interface level of the opposite surface 31b to be reduced, so that the dark-state properties of the pixel array part 11 can be improved.

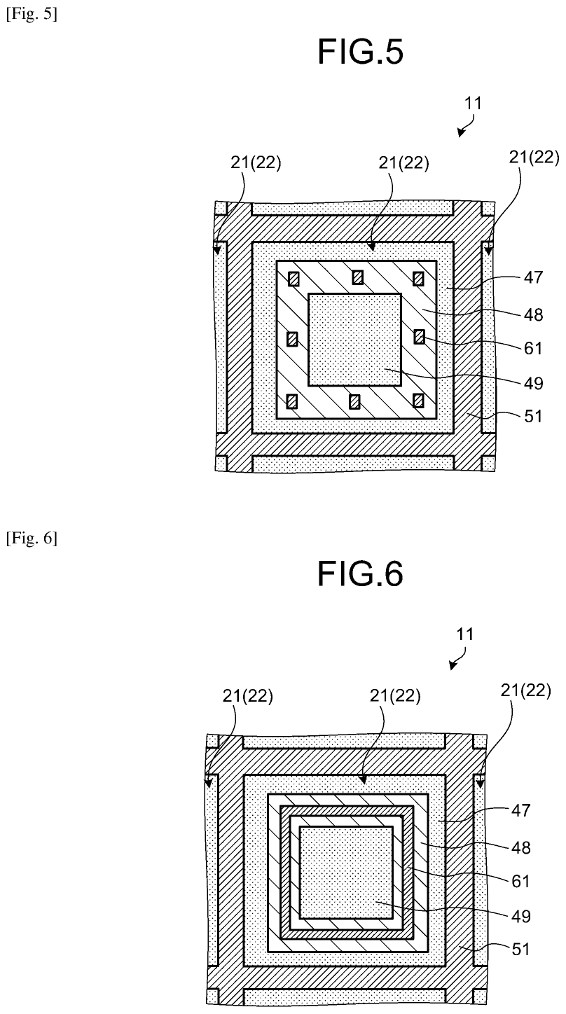

FIG. 5 is a view illustrating one example of a planer configuration at a depth D1 illustrated in FIG. 4. As illustrated in FIG. 5, in the pixel array part 11, each SPAD element 22 is isolated electrically and optically by providing the inter-pixel separating part 51 between the SPAD elements 22 adjacent to each other.

In the embodiment, the buried layer 48 with a frame shape is formed to surround the surface pinning layer 49, for example, in planar view, and the anode contact region 47 with a frame shape is formed to surround such a buried layer 48. In the buried layer 48, a plurality of the cathode electrodes 61 (eight in the figure) are equally disposed in a peripheral direction.

Note that the placement of the cathode electrodes 61 in the buried layer 48 is not limited to the example of FIG. 5. For example, as illustrated in FIG. 6, the cathode electrode 61 with a frame shape in planar view may be disposed along the buried layer 48. FIG. 6 is a view illustrating another example of the planer configuration at the depth D1 illustrated in FIG. 4. As shown in FIGS. 5 and 6, in the plan view, the cathode electrode 61 surrounds the center of the avalanche photodiode 22. Still with reference to FIGS. 5 and 6, the cathode electrode 61 is spaced apart from and surrounds the center of the avalanche photodiode 22. For example, all sides of the cathode electrode 61 are spaced apart from the center of the avalanche photodiode at a same distance. In FIG. 6, in the plan view, the cathode electrode 61 is contiguous. In FIG. 5 in the plan view, the cathode electrode 61 includes a plurality of cathode portions spaced apart from one another by the insulating layer 48. For example, each cathode portion is spaced apart from the center of the avalanche photodiode 22 at a same distance.

Return to the description of FIG. 4. As illustrated in FIG. 4, for example, the inter-pixel separating part 51 is formed to penetrate from the incident surface 31a of the semiconductor layer 31 to the opposite surface 31b thereof. For example, the inter-pixel separating part 51 has a triple structure configured with a metal film 52, an insulating film 53, and a fixed-charge film 54 in order from the inside.

For example, the metal film 52 is configured with a metal reflecting light (e.g., tungsten). For example, the insulating film 53 is configured with an insulator, such as silicon oxide (SiO₂).

The fixed-charge film 54 is formed, using a high dielectric having negative fixed charges, such that a positive-charge (hole) accumulating region is formed in an interface part with the pinning layer 46 to reduce the occurrence of the dark current. The fixed-charge film 54 is formed to have negative fixed electric charges, so that an electric field is applied to the interface with the pinning layer 46 by the negative fixed charges, and the positive-charge (hole) accumulating region is formed.

For example, the fixed-charge film 54 can be formed of a hafnium oxidation film (HfO₂ film). Additionally, for example, the fixed-charge film 54 can be formed to include at least one of oxides, such as hafnium, zirconium, aluminum, tantalum, titanium, magnesium, yttrium, and lanthanoid.

The sensor-side wiring layer 32 has the cathode electrode 61, the anode electrode 62, the contact electrode 63, a metal wiring 64, a contact electrode 65, and a metal pad (or bonding pad) 66. Note that, in the sensor-side wiring layer 32, an inter-layer insulating film is formed in a place other than these parts.

Each of the cathode electrode 61, the anode electrode 62, and the contact electrode 63 is electrically connected to the corresponding metal pad 66 via the metal wiring 64 and the contact electrode 65.

The logic-side wiring layer 33 has a metal pad (or bonding pad) 71, a contact electrode 72, an electrode pad 73, and an insulating layer 74. Note that, in the logic-side wiring layer 33, an inter-layer insulating film is formed in a place other than these parts.

Each metal pad 66 corresponding to the cathode electrode 61, the anode electrode 62, and the contact electrode 63 is electrically connected to the corresponding electrode pad 73 via the metal pad 71 and the contact electrode 72. The insulating layer 74 insulates the electrode pad 73 and the adjacent one.

That is, the cathode contact region 44, the anode contact region 47 and the surface pinning layer 49 are electrically connected to the corresponding electrode pad 73 via various kinds of wiring formed in the sensor-side wiring layer 32 and the logic-side wiring layer 33.

The planarized layer 34 is formed in tight contact with the whole incident surface 31a of the semiconductor layer 31 and provided to planarize the incident surface 31a of the semiconductor layer 31. The planarized layer 34 is configured with a material penetrating the reflected light L2 (e.g., a permeable resin material).

For example, the on-chip lens 35 is formed for each pixel 21 and condenses the reflected light L2 incident on the corresponding pixel 21. Note that, for example, the on-chip lens 35 may be formed for a plurality of the pixels 21 that are adjacent to each other, without being limited to the case where it is formed for each pixel 21.

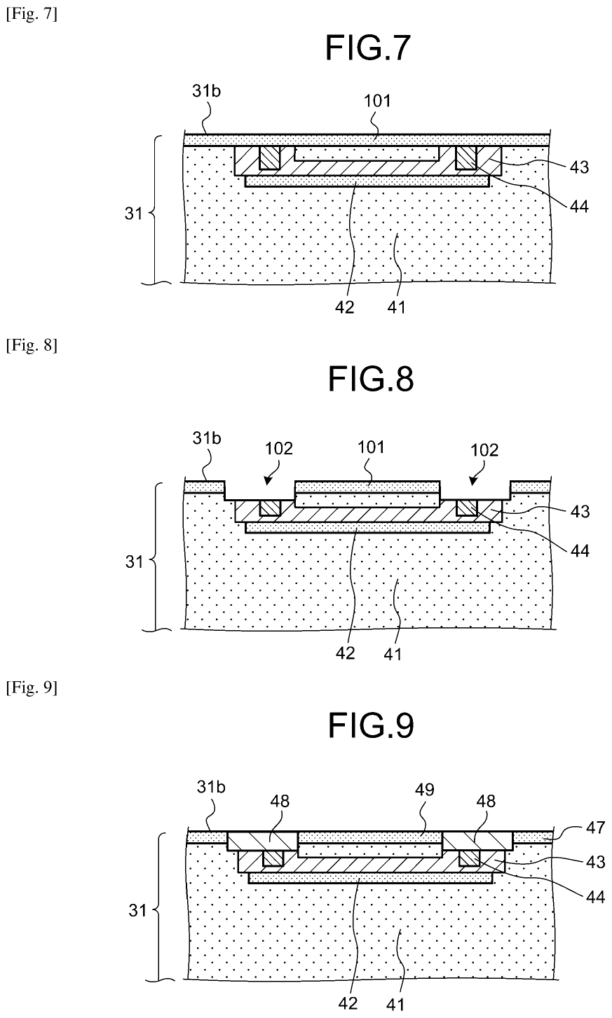

Manufacturing Process of Pixel Array Part Next, a manufacturing process of the pixel array part 11 according to the embodiment, in particular, a forming process of the buried layer 48 will be described with reference to FIGS. 7 to 12. FIGS. 7 to 12 are sectional views schematically illustrating one manufacturing process of the pixel array part 11 according to the embodiment of the present disclosure.

As illustrated in FIG. 7, the P-type diffusion layer 42, the N-type diffusion layer 43, the cathode contact region 44, and a P-type diffusion layer 101 are formed by a well-known technique in the vicinity of the opposite surface 31b of the semiconductor layer 31 where its impurity concentration is controlled to be P-type (i.e., the P well 41 is provided). The P-type diffusion layer 101, which is a concentrated P-type diffusion layer (P+), is formed on the whole surface of the opposite surface 31b.

Note that, in the state of FIG. 7, the incident surface 31a side of the semiconductor layer 31 is not ground, so that the semiconductor layer 31 in the state of FIG. 7 is in a state where it is thicker than the semiconductor layer 31 illustrated in FIG. 4.

Furthermore, the hole-accumulating layer 45, the pinning layer 46, the inter-pixel separating part 51, the planarized layer 34, the on-chip lens 35, and other parts are formed after the semiconductor layer 31 is ground to a predetermined thickness, so that these parts are not formed in the state of FIG. 7.

As illustrated in FIG. 8, in the surface of the opposite surface 31b, a hole part 102 is then formed by a well-known technique such that at least the cathode contact region 44 is exposed in its bottom surface. Such a hole part 102 is formed at a position corresponding to the buried layer 48.

As illustrated in FIG. 9, the buried layer 48 is then formed by burying the inside of the hole part 102 with an insulator using a well-known technique. Note that forming such a buried layer 48 causes the P-type diffusion layer 101 to be separated into the anode contact region 47 and the surface pinning layer 49.

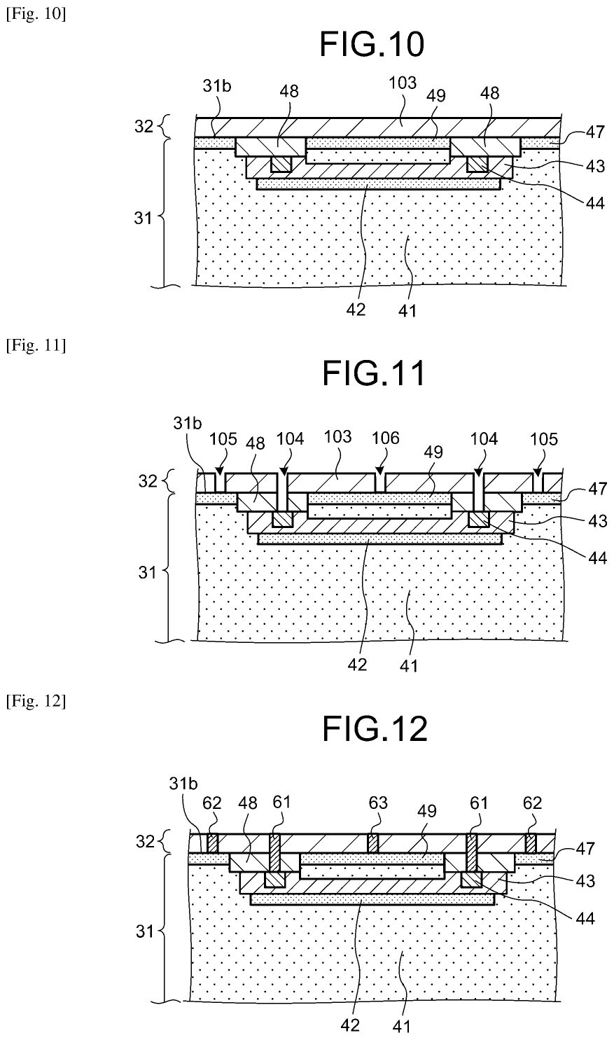

As illustrated in FIG. 10, an insulating layer 103 having a predetermined thickness is then formed on the surface of the opposite surface 31b by a well-known technique. Note that such an insulating layer 103 is a part corresponding to a part of the inter-layer insulating film of the sensor-side wiring layer 32.

As illustrated in FIG. 11, in the surface of the insulating layer 103, a hole part 104 is then formed by a well-known technique such that at least the cathode contact region 44 is exposed in its bottom surface. This hole part 104 is formed at a position corresponding to the cathode electrode 61.

Furthermore, in the surface of the insulating layer 103, a hole part 105 is formed by a well-known technique such that at least the anode contact region 47 is exposed in its bottom surface. Such a hole part 105 is formed at a position corresponding to the anode electrode 62.

Furthermore, in the surface of the insulating layer 103, a hole part 106 is then formed by a well-known technique such that at least the surface pinning layer 49 is exposed in its bottom surface. Such a hole part 106 is formed at a position corresponding to the contact electrode 63.

As illustrated in FIG. 12, the cathode electrode 61, the anode electrode 62, and the contact electrode 63 are then formed by burying the inside of the hole parts 104 to 106 with a metal using a well-known technique.

At the following process, the desired sensor-side wiring layer 32 is formed by a well-known technique while the logic-side wiring layer 33 is formed on the logic-side substrate by a well-known technique. After then, using a technique such as Cu—Cu bonding, the sensor-side wiring layer 32 is bonded to the logic-side wiring layer 33.

A surface on the opposite side to the sensor-side wiring layer 32 of the semiconductor layer 31 is then ground to a predetermined thickness by a well-known technique, and the incident surface 31a is formed. After then, from the incident surface 31a side of the semiconductor layer 31, the hole-accumulating layer 45, the pinning layer 46, the inter-pixel separating part 51, and other parts are formed by a well-known technique.

Finally, the planarized layer 34 and the on-chip lens 35 are formed on the incident surface 31a side of the semiconductor layer 31, and the pixel array part 11 according to the embodiment is completed.

Note that the manufacturing process of the pixel array part 11 according to the embodiment is not limited to the above process. For example, the buried layer 48 and the insulating layer 103 may be formed at the same process in the case where the same material is acceptable to the buried layer 48 and the insulating layer 103.

From the state illustrated in FIG. 9, the insulating layer 103 may be formed after forming a part of the cathode electrode 61 in the buried layer 48.

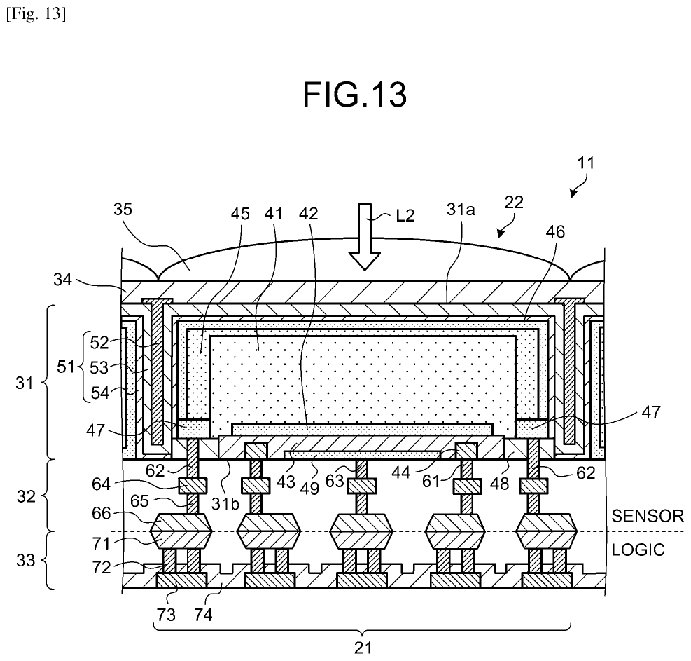

Various Variations Next, various variations of the embodiment will be described with reference to FIGS. 13 to 15. FIG. 13 is a sectional view illustrating a configuration example of the pixel array part 11 according to of a first variation of the embodiment of the present disclosure.

In the embodiment described above, the example where the buried layer 48 is provided between the cathode contact region 44 and the opposite surface 31b of the semiconductor layer 31 is illustrated, but the buried layer 48 may be provided between the anode contact region 47 and the opposite surface 31b of the semiconductor layer 31.

For example, as illustrated in FIG. 13, the buried layer 48 is disposed between the anode contact region 47 and the opposite surface 31b of the semiconductor layer 31 while the cathode contact region 44 is disposed in contact with the opposite surface 31b of the semiconductor layer 31.

Also in such a configuration, the gap between the cathode contact region 44 and the anode contact region 47 can be insulated and separated while being spaced not only in the horizontal direction but also in the vertical direction. This can achieve the relaxation of the electric field between the cathode contact region 44 and the anode contact region 47 while preventing the area of the pixel array part 11 from expanding.

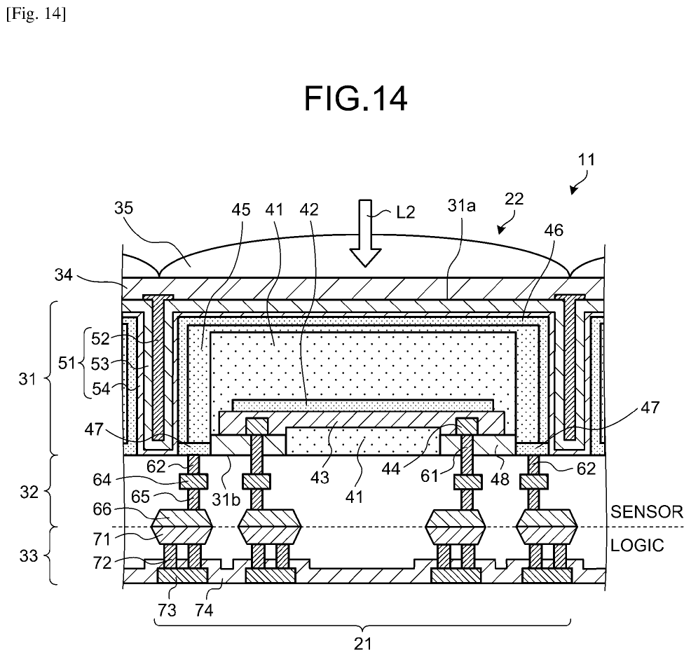

FIG. 14 is a sectional view illustrating a configuration example of the pixel array part 11 according to a second variation of the embodiment of the present disclosure. As illustrated in FIG. 14, the pixel array part 11 according to the second variation is an example where no surface pinning layer 49 is provided on the opposite surface 31b side of the semiconductor layer 31.

In this second variation, no surface pinning layer 49 is provided in the semiconductor layer 31, so that various kinds of wiring to connect such a surface pinning layer 49 to the ground potential is unnecessary. In the second variation, the configuration of the sensor-side wiring layer 32 and the logic-side wiring layer 33 thus can be simplified, so that the cost of manufacturing the pixel array part 11 can be reduced.

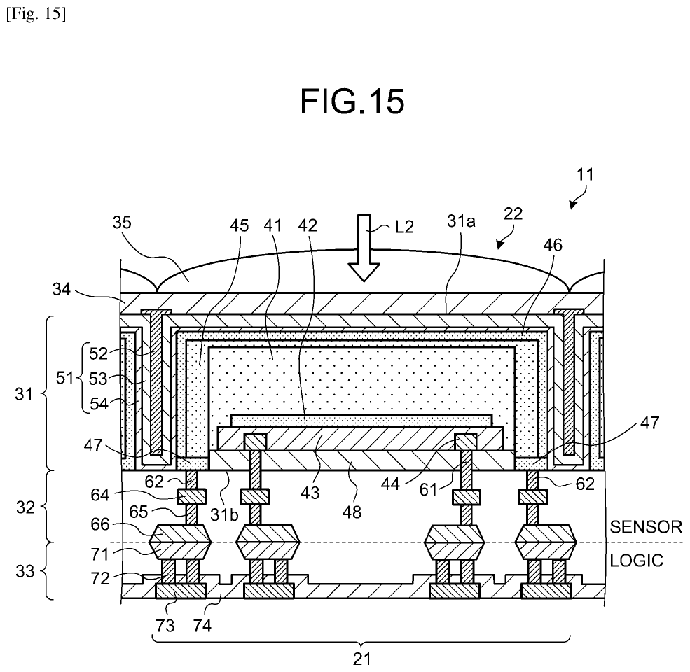

FIG. 15 is a sectional view illustrating a configuration example of the pixel array part 11 according to a third variation of the embodiment of the present disclosure. As illustrated in FIG. 15, the pixel array part 11 according to the third variation is an example where the gap between the N-type diffusion layer 43 and the opposite surface 31b of the semiconductor layer 31 is wholly covered with the buried layer 48. That is, in the plan view, the insulating layer 48 extends between two sides (e.g., inner sides) of the cathode electrode 61.

Also in this third variation, no surface pinning layer 49 is provided in the semiconductor layer 31 similarly to the second variation described above, so that various kinds of wiring to connect such a surface pinning layer 49 to the ground potential is unnecessary. In the third variation, the configuration of the sensor-side wiring layer 32 and the logic-side wiring layer 33 thus can be simplified, so that the cost of manufacturing the pixel array part 11 can be reduced.

### Effects

The light receiving element (pixel array part 11) according to the embodiment includes the SPAD element 22, the cathode electrode 61 and the anode electrode 62, the cathode contact region 44, the anode contact region 47, and the buried layer 48. The SPAD element 22 is formed in the semiconductor layer 31 and provided for each of the pixels 21 disposed into an array form. The cathode electrode 61 and the anode electrode 62 is formed at least partially in the wiring layer (sensor-side wiring layer 32) adjacent to the semiconductor layer 31 and applies the reverse bias voltage to the SPAD element 22. The N-type cathode contact region 44 is formed in the semiconductor layer 31 and directly connected to the cathode electrode 61. The P-type anode contact region 47 is formed in the semiconductor layer 31 and directly connected to the anode electrode 62. The insulating buried layer 48 is located between either one of the cathode contact region 44 and the anode contact region 47, and the surface (opposite surface 31b) on the opposite side to the light incident side of the semiconductor layer 31.

This can achieve the relaxation of the electric field between the cathode contact region 44 and the anode contact region 47 while preventing the area of the pixel array part 11 from expanding.

The light receiving element (pixel array part 11) according to the embodiment is formed in the surface (opposite surface 31b) on the opposite side to the light incident side of the semiconductor layer 31 and further includes the surface pinning layer 49 connected to the ground potential.

This can improve the dark-state properties of the pixel array part 11.

The light receiving element (pixel array part 11) according to the embodiment further includes the N-type diffusion layer 43 in contact with the cathode contact region 44 in the semiconductor layer 31. The gap between the N-type diffusion layer 43 and the surface (opposite surface 31b) on the opposite side to the light incident side of the semiconductor layer 31 is covered with the buried layer 48.

This can reduce the cost of manufacturing the pixel array part 11.

Electronic Device

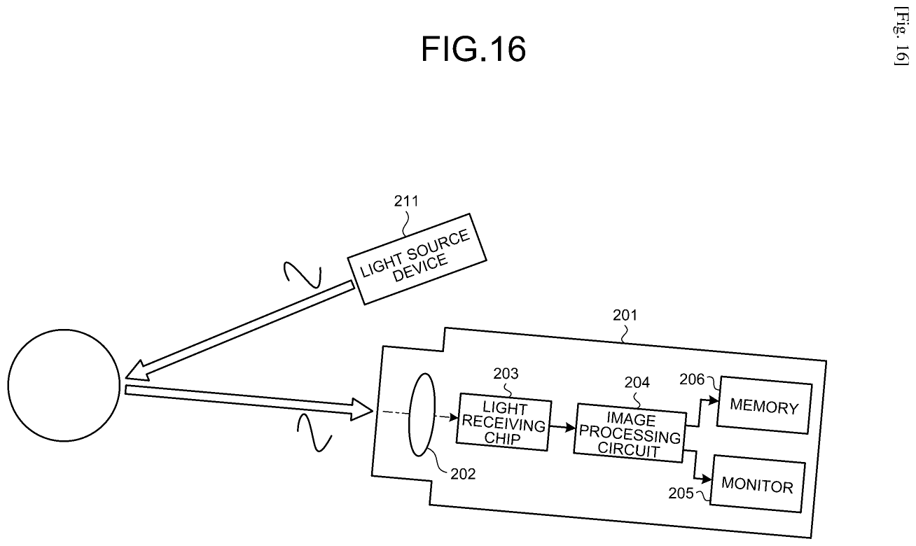

FIG. 16 is a block diagram illustrating a configuration example of a range image sensor that is an electronic device using the light receiving chip 3.

As illustrated in FIG. 16, the range image sensor 201 includes an optical system 202, a light receiving chip 203, an image processing circuit 204, a monitor 205, and a memory 206. The range image sensor 201 receives light (modulation light or pulse light) that is projected from a light source device 211 toward an object and reflected on the surface of the subject, and thus can acquire a range image corresponding to the distance to the object.

The optical system 202 has one or more lenses and leads image light (incident light) from the object to the light receiving chip 203 to cause the pixel array part 11 of the light receiving chip 203 to form an image.

The light receiving chip 3 of each embodiment described above is applied to the light receiving chip 203, and a distance signal indicating the distance determined from the light reception signal (APD OUT) output from the light receiving chip 203 is supplied to the image processing circuit 204.

The image processing circuit 204 performs an image processing to configure a range image based on the distance signal supplied from the light receiving chip 203. The range image (image data) obtained through the image processing in such an image processing circuit 204 is supplied to the monitor 205 to be displayed, or is supplied to the memory 206 to be stored (recorded).

The range image sensor 201 configured in this way, to which the light receiving chip 3 described above is applied, can use the light receiving chip 3 achieving the relaxation of the electric field between the cathode contact region 44 and the anode contact region 47 while preventing the area of the pixel array part 11 from expanding.

Application to Mobile

The technology (the present technology) according to the present disclosure can be applied to various products. For example, the technology according to the present disclosure may be implemented as a device installed in any type of mobiles, such as a car, an electric car, a hybrid electric car, a motorcycle, a bicycle, a personal mobility, an airplane, a drone, a ship, and a robot.

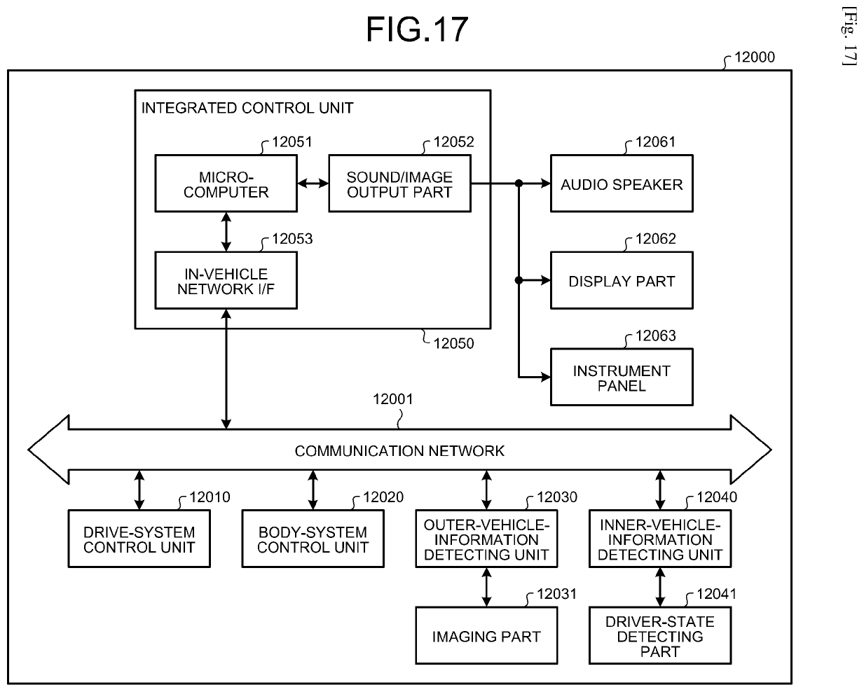

FIG. 17 is a block diagram illustrating a schematic configuration example of a vehicle control system that is one example of a mobile control system where the technology according to the present disclosure can be applied.

The vehicle control system 12000 includes a plurality of electronic control units connected via a communication network 12001. In the example illustrated in FIG. 17, the vehicle control system 12000 includes a drive-system control unit 12010, a body-system control unit 12020, an outer-vehicle-information detecting unit 12030, inner-vehicle-information detecting unit 12040, and an integrated control unit 12050. As a function configuration of the integrated control unit 12050, a microcomputer 12051, a sound/image output part 12052, and an in-vehicle network interface (I/F) 12053 are illustrated.

The drive-system control unit 12010 controls the operation of a device associated with a drive system of the vehicle, according to various computer programs. For example, the drive-system control unit 12010 functions as a controller for a driving-force generating device to generate a driving force of the vehicle, such as an internal combustion engine or a driving motor, a driving-force transmission mechanism to transmit the driving force to a wheel, a steering mechanism to adjust a steering angle of the vehicle, a braking device generating a braking force of the vehicle, and other devices.

The body-system control unit 12020 controls the operation of various devices equipped in the body, according to various computer programs. For example, the body-system control unit 12020 functions as a controller for a keyless entry system, a smart key system, a power window device, or various lamps, such as a head lamp, a back lamp, a brake lamp, a blinker or a fog lamp. In this case, a radio wave sent from a portable machine substituting a key, or a signal from various switches may be input to the body-system control unit 12020. The body-system control unit 12020 accepts the input of this radio wave or signal and controls a door-locking device, a power window device, a lamp, or other devices of the vehicle.

The outer-vehicle-information detecting unit 12030 detects information outside the vehicle installing the vehicle control system 12000. For example, an imaging part 12031 is connected to the outer-vehicle-information detecting unit 12030. The outer-vehicle-information detecting unit 12030 causes the imaging part 12031 to image an image outside the vehicle and receives the imaged image. The outer-vehicle-information detecting unit 12030 may perform, based on the received image, an object detecting process or a distance detecting process for a person, a vehicle, an obstacle, a mark or a character on a road surface, and other objects.

The imaging part 12031 is an optical sensor that receives light and outputs an electrical signal corresponding to the light receiving amount of the light. The imaging part 12031 can output the electrical signal as an image or can output it as information for the distance measurement. Furthermore, the light received by the imaging part 12031 may be visible light or may be non-visible light, such as infrared rays.

The inner-vehicle-information detecting unit 12040 detects information inside the vehicle. For example, a driver-state detecting part 12041 detecting the state of a driver is connected to the inner-vehicle-information detecting unit 12040. The driver-state detecting part 12041 includes a camera imaging, for example, a driver, and the inner-vehicle-information detecting unit 12040 may calculate the fatigue level or concentration level of the driver or may determine whether the driver is not dozing off, based on detection information input from the driver-state detecting part 12041.

The microcomputer 12051 can operate a control target value for the driving-force generating device, the steering mechanism, or the brake device, and output a control command to the drive-system control unit 12010, based on the information inside or outside the vehicle acquired by the outer-vehicle-information detecting unit 12030 or the inner-vehicle-information detecting unit 12040. For example, the microcomputer 12051 can perform cooperative control intended for implementing the function of an advanced driver assistance system (ADAS) including, for example, collision avoidance or shock mitigation of the vehicle, following travel based on an inter-vehicle distance, vehicle-speed maintaining travel, a warning about a collision of the vehicle, or a warning about a deviation of the vehicle from a lane.

Furthermore, the microcomputer 12051 can perform cooperative control intended for, for example, automatic operation for traveling autonomously without driver's operation, by controlling the driving-force generating device, the steering mechanism, the brake device, or other devices based on the information around the vehicle acquired by the outer-vehicle-information detecting unit 12030 or the inner-vehicle-information detecting unit 12040.

The microcomputer 12051 can output the control command to the body-system control unit 12020 based on the information outside the vehicle acquired by the outer-vehicle-information detecting unit 12030. For example, the microcomputer 12051 can control a head lamp depending on the position of a preceding vehicle or an oncoming vehicle detected by the outer-vehicle-information detecting unit 12030 and perform cooperative control intended for achieving glare protection, for example, switching a high beam to a low beam.

The sound/image output part 12052 transmits an output signal of at least one of a voice and an image to an output device that can notify an occupant of the vehicle or the outside of the vehicle of information visually or audibly. In the example of FIG. 17, an audio speaker 12061, a display part 12062, and an instrument panel 12063 are exemplified as the output device. For example, the display part 12062 may include at least one of an on-board display and a head-up display.

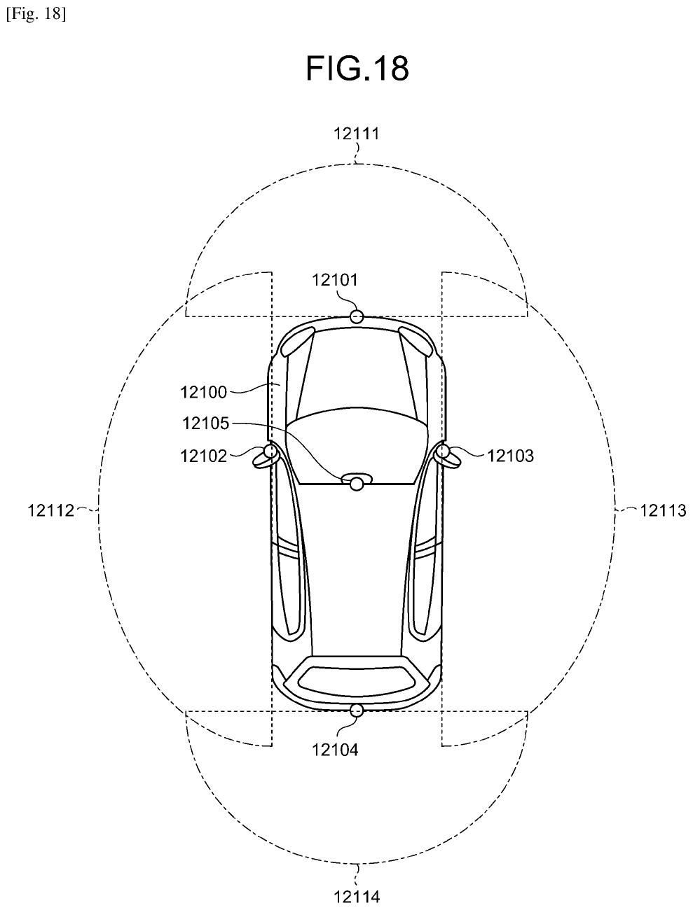

FIG. 18 is a view illustrating an example of an installation position of the imaging part 12031.

In FIG. 18, as the imaging part 12031, the imaging parts 12101, 12102, 12103, 12104, and 12105 are provided.

The imaging parts 12101, 12102, 12103, 12104, and 12105 are provided at the positions of, for example, a front nose, side mirrors, a rear bumper, and a back door of a vehicle 12100, as well as the top of a windshield in a vehicle room thereof. The imaging part 12101 provided at the front nose and the imaging part 12105 provided at the top of the windshield in the vehicle room mainly acquire an image in front of the vehicle 12100. The imaging parts 12102 and 12103 provided at the side mirrors mainly acquire an image on the side of the vehicle 12100. The imaging part 12104 provided at the rear bumper or the back door mainly acquires an image behind the vehicle 12100. The imaging part 12105 provided at the top of the windshield in the vehicle room is mainly used for detecting, for example, a preceding vehicle, or a walker, an obstacle, a signaling device, a traffic sign or a traffic lane.

Note that FIG. 18 illustrates one example of the imaging ranges of the imaging parts 12101 to 12104. The imaging range 12111 indicates the imaging range of the imaging part 12101 provided at the front nose; the imaging ranges 12112 and 12113 indicate the imaging ranges of the imaging parts 12102 and 12103 provided at the side mirrors, respectively; and the imaging range 12114 indicates the imaging range of the imaging part 12104 provided at the rear bumper or the back door. For example, superimposing pieces of image data imaged by the imaging parts 12101 to 12104 yields a bird's-eye image where the vehicle 12100 is viewed from above.

At least one of the imaging parts 12101 to 12104 may have a function acquiring distance information. For example, at least one of the imaging parts 12101 to 12104 may be a stereoscopic camera configured with a plurality of imaging elements, or may be an imaging element having a pixel for phase-difference detection.

For example, the microcomputer 12051 can determine the distances to respective three-dimensional objects in the imaging range 12111 to 12114 and temporal changes in these distances (relative velocities to the vehicle 12100) based on the distance information obtained from the imaging parts 12101 to 12104, thereby extracting, as a preceding vehicle, a three-dimensional object that is the nearest three-dimensional object particularly on the traveling route of the vehicle 12100 and is traveling at a predetermined speed (e.g., 0 km/h or more) in almost the same direction as that of the vehicle 12100. Furthermore, the microcomputer 12051 can set an inter-vehicle distance to be previously secured in front of a preceding vehicle, and perform, for example, automatic brake control (also including following-stop control) and automatic acceleration control (also including following-start control). In this way, the cooperative control intended for, for example, automatic operation for traveling autonomously without driver's operation can be performed.

For example, the microcomputer 12051 can classify, based on the distance information obtained from the imaging parts 12101 to 12104, three-dimensional-object data about a three-dimensional object into a bike, a common vehicle, a large vehicle, a walker, an electricity pole, and other three-dimensional objects and extract the classified data to use it for automatic avoidance of an obstacle. For example, the microcomputer 12051 distinguishes between an obstacle that is visible for a driver of the vehicle 12100 and an obstacle that is hard to be visible for the driver, among obstacles around the vehicle 12100. After then, the microcomputer 12051 determines a collision risk indicating the risk of a collision with each obstacle, and, in the situation where the collision risk is in a set value or more and thus there is a possibility of the collision, can perform operation support for collision avoidance by outputting a warning to the driver via the audio speaker 12061 and the display part 12062 or performing forced deceleration and avoidance steering via the drive-system control unit 12010.

At least one of the imaging parts 12101 to 12104 may be an infrared camera detecting infrared rays. For example, the microcomputer 12051 can identify a walker by determining whether the walker exists in the image imaged by the imaging parts 12101 to 12104. Such a walker identification is performed, for example, through a procedure to extract feature points in the image imaged by the imaging parts 12101 to 12104 as the infrared camera and a procedure to perform a pattern matching process on a series of feature points indicating the contour of an object to determine whether it is a walker. When the microcomputer 12051 determines that a walker exists in the image imaged by the imaging parts 12101 to 12104 and identifies the walker, the sound/image output part 12052 controls the display part 12062 so as to superpose and display a square contour line for emphasis on the identified walker. Furthermore, the sound/image output part 12052 may control the display part 12062 so as to display, for example, an icon indicating the walker, at a desired position.

One example of the vehicle control system to which the technology according to the present disclosure can be applied has been described. The technology according to the present disclosure can be applied to the imaging part 12031 in the configuration described above. Specifically, the distance-measurement device 1 in FIG. 1 can be applied to the imaging part 12031. The technology according to the present disclosure is applied to the imaging part 12031, so that the light receiving chip 3 achieving the relaxation of the electric field between the cathode contact region 44 and the anode contact region 47 while preventing the area of the pixel array part 11 from expanding can be used.

The embodiment of the present disclosure has been described, but the technical scope of the present disclosure is not limited the embodiment described above as it is, and various kinds of changes are possible without departing from the subject matter of the present disclosure. Furthermore, components over different embodiments and variations may be combined as necessary.

For example, in the element structure of the pixel array part 11 illustrated in the embodiment described above, an element structure where a P-type conduction type and an N-type conduction type are exchanged may be used as the embodiment.

The effect described in the specification is only exemplified, without limitation, and there may be other effects.

Note that the present technology can also have the following configuration.

(1) A light receiving element comprising:
a single photon avalanche diode (SPAD) element formed in a semiconductor layer and provided for each of pixels disposed into an array form;
a cathode electrode and an anode electrode formed at least partially in a wiring layer adjacent to the semiconductor layer and configured to apply a reverse bias voltage to the SPAD element;
an N-type cathode contact region formed in the semiconductor layer and directly connected to the cathode electrode;
a P-type anode contact region formed in the semiconductor layer and directly connected to the anode electrode; and
an insulating buried layer located between either one of the cathode contact region and the anode contact region, and a surface on an opposite side to a light incident side of the semiconductor layer.
(2) The light receiving element according to (1), further comprising a surface pinning layer formed in the surface on the opposite side to the light incident side of the semiconductor layer and connected to a ground potential.
(3) The light receiving element according to one or more of (1) to (2), further comprising an N-type diffusion layer in contact with the cathode contact region in the semiconductor layer, wherein a gap between the N-type diffusion layer and the surface on the opposite side to the light incident side of the semiconductor layer is covered with the buried layer.

(4) An electronic device, comprising a light receiving element that comprises:
a single photon avalanche diode (SPAD) element formed in a semiconductor layer and provided for each of pixels disposed into an array form;
a cathode electrode and an anode electrode formed at least partially in a wiring layer adjacent to the semiconductor layer and configured to apply a reverse bias voltage to the SPAD element;
an N-type cathode contact region formed in the semiconductor layer and directly connected to the cathode electrode;
a P-type anode contact region formed in the semiconductor layer and directly connected to the anode electrode; and
an insulating buried layer located between either one of the cathode contact region and the anode contact region, and a surface on an opposite side to a light incident side of the semiconductor layer.

(5) The electronic device according to (4), wherein the light receiving element further comprises a surface pinning layer formed in the surface on the opposite side to the light incident side of the semiconductor layer and connected to a ground potential.

(6) The electronic device according to one or more of (4) to (5), wherein the light receiving element further comprises an N-type diffusion layer in contact with the cathode contact region in the semiconductor layer, and a gap between the N-type diffusion layer and the surface on the opposite side to the light incident side of the semiconductor layer is covered with the buried layer.

(7) An avalanche photodiode, comprising:
a substrate including a first side with a first surface and a second side with a second surface that is opposite the first surface, the second surface being a light-incident surface of the substrate;
an anode region disposed in the substrate at the first side of the substrate;
an anode electrode coupled to the anode region;
a cathode region disposed in the substrate at the first side of the substrate; and
a cathode electrode coupled to the cathode region;
an insulating layer disposed in the substrate at the first side of the substrate, wherein the anode electrode or the cathode electrode passes through the insulating layer.

(8) The avalanche photodiode of (7), wherein, in a plan view, the cathode electrode is disposed closer to a center of the avalanche photodiode than the anode electrode.

(9) The avalanche photodiode of one or more of (7) to (8), wherein, in the plan view, the cathode electrode surrounds the center of the avalanche photodiode.

(10) The avalanche photodiode of one or more of (7) to (9), wherein, in the plan view, the cathode electrode is spaced apart from and surrounds the center of the avalanche photodiode.

(11) The avalanche photodiode of one or more of (7) to (10), wherein, in the plan view, the cathode electrode is contiguous.

(12) The avalanche photodiode of one or more of (7) to (11), wherein all sides of the cathode electrode are spaced apart from the center of the avalanche photodiode at a same distance.

(13) The avalanche photodiode of one or more of (7) to (12), wherein, in the plan view, the cathode electrode includes a plurality of cathode portions spaced apart from one another by the insulating layer.

(14) The avalanche photodiode of one or more of (7) to (13), wherein each cathode portion is spaced apart from the center of the avalanche photodiode at a same distance.

(15) The avalanche photodiode of one or more of (7) to (14), wherein, in the plan view, the insulating layer extends between two sides of the cathode electrode.

(16) The avalanche photodiode of one or more of (7) to (15), wherein a surface of the insulating layer is coplanar with the first surface of the substrate.

(17) The avalanche photodiode of one or more of (7) to (16), wherein the insulating layer extends deeper into the substrate than the anode contact region.

(18) The avalanche photodiode of one or more of (7) to (17), further comprising:
a doped region extending between two sides of the insulating layer.

(19) The avalanche photodiode of one or more of (7) to (18), further comprising:
a contact electrode coupled to the doped region and to a node that receives a potential.

(20) The avalanche photodiode of one or more of (7) to (19), wherein the potential is a ground potential.

(21) A light detecting device, comprising:
a first substrate including a first side with a first surface and a second side with a second surface that is opposite the first surface, the second surface being a light-incident surface of the first substrate;
an avalanche photodiode including:
   an anode region disposed in the first substrate at the first side of the first substrate;
   an anode electrode coupled to the anode region;
   a cathode region disposed in the first substrate at the first side of the first substrate;
   an insulating layer disposed in the first substrate at the first side of the first substrate;
   a cathode electrode coupled to the cathode region, wherein the cathode electrode or the anode electrode passes through the insulating layer; and
a first wiring layer on the first surface of the first substrate and including:
   an anode wiring coupled to the anode electrode;
   a cathode wiring coupled to the cathode electrode; and
   a plurality of first bonding pads;
      and
a second substrate including a second wiring layer and circuitry to process signals output from the avalanche photodiode, the second wiring layer including a plurality of second bonding pads bonded to the plurality of first bonding pads.

(22) The light detecting device of (21), wherein the plurality of first bonding pads and the plurality of second bonding pads each include a bonding pad electrically connected to the anode wiring and a bonding pad electrically connected to the cathode wiring.

(23) The light detecting device of one or more of (21) to (22), wherein, in a plan view, the cathode electrode is disposed closer to a center of the avalanche photodiode than the anode electrode.

(24) The light detecting device of one or more of (21) to (23), wherein, in the plan view, the cathode electrode surrounds the center of the avalanche photodiode.

(25) The light detecting device of one or more of (21) to (24), wherein, in the plan view, the cathode electrode is spaced apart from and surrounds the center of the avalanche photodiode.

(26) An electronic apparatus, comprising:
a light source that emits modulated light toward and object; and
an avalanche photodiode that senses the modulated light reflected from the object, the avalanche photodiode including:
   a substrate including a first side with a first surface and a second side with a second surface that is opposite the first surface, the second surface being a light-incident surface of the substrate;
   an anode region disposed in the substrate at the first side of the substrate;
   an anode electrode coupled to the anode region;
   a cathode region disposed in the substrate at the first side of the substrate;
   an insulating layer disposed in the substrate at the first side of the substrate; and
   a cathode electrode coupled to the cathode region, wherein the cathode electrode or the anode electrode passes through the insulating layer.

### REFERENCE SIGNS LIST

1 Distance-measurement device
3 Light receiving chip
11 Pixel array part (one example of light receiving element)
21 Pixel
22 SPAD element
31 Semiconductor layer
31a Incident surface
31b Opposite surface
32 Sensor-side wiring layer (one example of wiring layer)
43 N-type diffusion layer
44 Cathode contact region
47 Anode contact region
48 Buried layer
49 Surface pinning layer
61 Cathode electrode
62 Anode electrode

What is claimed is:

1. An avalanche photodiode, comprising:
a substrate including a first side with a first surface and a second side with a second surface that is opposite the first surface, the second surface being a light-incident surface of the substrate;
an anode region disposed in the substrate at the first side of the substrate;
an anode electrode coupled to the anode region;
a cathode region disposed in the substrate at the first side of the substrate;
a cathode electrode coupled to the cathode region; and
an insulating layer disposed in the substrate at the first side of the substrate, wherein the anode electrode or the cathode electrode passes through the insulating layer.

2. The avalanche photodiode of claim 1, wherein, in a plan view, the cathode electrode is disposed closer to a center of the avalanche photodiode than the anode electrode.

3. The avalanche photodiode of claim 2, wherein, in the plan view, the cathode electrode surrounds the center of the avalanche photodiode.

4. The avalanche photodiode of claim 3, wherein, in the plan view, the cathode electrode is spaced apart from and surrounds the center of the avalanche photodiode.

5. The avalanche photodiode of claim 4, wherein, in the plan view, the cathode electrode is contiguous.

6. The avalanche photodiode of claim 5, wherein all sides of the cathode electrode are spaced apart from the center of the avalanche photodiode at a same distance.

7. The avalanche photodiode of claim 3, wherein, in the plan view, the cathode electrode includes a plurality of cathode portions spaced apart from one another by the insulating layer.

8. The avalanche photodiode of claim 7, wherein each cathode portion is spaced apart from the center of the avalanche photodiode at a same distance.

9. The avalanche photodiode of claim 3, wherein, in the plan view, the insulating layer extends between two sides of the cathode electrode.

10. The avalanche photodiode of claim 1, wherein a surface of the insulating layer is coplanar with the first surface of the substrate.

11. The avalanche photodiode of claim 10, wherein the insulating layer extends deeper into the substrate than the anode contact region.

12. The avalanche photodiode of claim 3, further comprising:
a doped region extending between two sides of the insulating layer.

13. The avalanche photodiode of claim 12, further comprising:
a contact electrode coupled to the doped region and to a node that receives a potential.

14. The avalanche photodiode of claim 13, wherein the potential is a ground potential.

15. A light detecting device, comprising:
a first substrate including a first side with a first surface and a second side with a second surface that is opposite the first surface, the second surface being a light-incident surface of the first substrate;
an avalanche photodiode including:
an anode region disposed in the first substrate at the first side of the first substrate;
an anode electrode coupled to the anode region;
a cathode region disposed in the first substrate at the first side of the first substrate;
an insulating layer disposed in the first substrate at the first side of the first substrate;
a cathode electrode coupled to the cathode region, wherein the cathode electrode or the anode electrode passes through the insulating layer; and
a first wiring layer on the first surface of the first substrate and including:
an anode wiring coupled to the anode electrode;
a cathode wiring coupled to the cathode electrode; and
a plurality of first bonding pads; and
a second substrate including a second wiring layer and circuitry to process signals output from the avalanche photodiode, the second wiring layer including a plurality of second bonding pads bonded to the plurality of first bonding pads.

16. The light detecting device of claim 15, wherein the plurality of first bonding pads and the plurality of second bonding pads each include a bonding pad electrically connected to the anode wiring and a bonding pad electrically connected to the cathode wiring.

17. The light detecting device of claim 16, wherein, in a plan view, the cathode electrode is disposed closer to a center of the avalanche photodiode than the anode electrode.

18. The light detecting device of claim 17, wherein, in the plan view, the cathode electrode surrounds the center of the avalanche photodiode.

19. The light detecting device of claim 18, wherein, in the plan view, the cathode electrode is spaced apart from and surrounds the center of the avalanche photodiode.

20. An electronic apparatus, comprising:
a light source that emits modulated light toward and object; and
an avalanche photodiode that senses the modulated light reflected from the object, the avalanche photodiode including:
a substrate including a first side with a first surface and a second side with a second surface that is opposite the first surface, the second surface being a light-incident surface of the substrate;
an anode region disposed in the substrate at the first side of the substrate;
an anode electrode coupled to the anode region;
a cathode region disposed in the substrate at the first side of the substrate;
an insulating layer disposed in the substrate at the first side of the substrate; and
a cathode electrode coupled to the cathode region, wherein the cathode electrode or the anode electrode passes through the insulating layer.
